(19) United States
(12) Patent Application Publication
(10) Pub. No.: US 2026/0005174 A1
(43) Pub. Date: Jan. 1, 2026

(54) SEMICONDUCTOR PACKAGE INCLUDING SOLDER STRUCTURE AND SEMICONDUCTOR MODULE INCLUDING THE SAME

(71) Applicant: SAMSUNG ELECTRONICS CO., LTD., SUWON-SI (KR)

(72) Inventor: Dahee Park, Suwon-si (KR)

(21) Appl. No.: 19/060,133

(22) Filed: Feb. 21, 2025

(30) Foreign Application Priority Data
Jul. 1, 2024 (KR) 10-2024-0086054

(51) Int. Cl. H01L 23/00; H01L 23/31

(52) U.S. Cl. CPC H01L 24/13; H01L 23/3171; H01L 24/16; H01L 24/81; H01L 24/05; H01L 24/32; H01L 24/73; H01L 2224/0401; H01L 2224/05568; H01L 2224/13076; H01L 2224/13111; H01L 2224/13113; H01L 2224/13139; H01L 2224/13147; H01L 2224/16227; H01L 2224/32225; H01L 2224/73204; H01L 2224/81193; H01L 2224/81935

(57) ABSTRACT

A semiconductor device includes a lower substrate. A first pad is disposed on the lower substrate. An upper substrate is disposed on the lower substrate. A second pad is disposed in a lower portion of the upper substrate. A solder structure is disposed between the first pad and the second pad. A coating layer covers at least a portion of an external surface of the solder structure. The solder structure includes a first portion disposed on a first surface that is in contact with the first pad. The first portion has a first solder pattern and a second solder pattern. The second solder pattern surrounds the first solder pattern.

### CROSS-REFERENCE TO RELATED APPLICATION(S)

This application claims priority under 35 U.S.C. § 119 to Korean Patent Application No. 10-2024-0086054, filed on Jul. 1, 2024, in the Korean Intellectual Property Office, the disclosure of which is herein incorporated by reference in its entirety.

### TECHNICAL FIELD

The present disclosure relates to a semiconductor package and a semiconductor module including the same. More particularly, the present disclosure relates to a semiconductor package including a solder structure and a semiconductor module including the same.

### DISCUSSION OF THE RELATED ART

A semiconductor package is a housing or enclosure that protects and supports a semiconductor chip, enabling it to be connected to external circuits. It serves several important functions such as protecting the chip from physical damage, providing means of interconnecting the chip to a printed circuit board (PCB), and helping to dissipate heat from the chip. The semiconductor package may be mounted on the PCB through a solder structure. The solder structure can be created using a reflow process, wherein connection bumps on the ball pads of the PCB are reflowed along with solder paste applied to the bonding pads of the PCB.

### SUMMARY

A semiconductor device includes a lower substrate. A first pad is disposed on the lower substrate. An upper substrate is disposed on the lower substrate. A second pad is disposed in a lower portion of the upper substrate. A solder structure is disposed between the first pad and the second pad. A coating layer covers at least a portion of an external surface of the solder structure. The solder structure includes a first portion disposed on a first surface that is in contact with the first pad. The first portion includes a first solder pattern and a second solder pattern. The second solder pattern surrounds the first solder pattern.

A semiconductor device includes a lower substrate. A first pad is disposed on the lower substrate. An upper substrate is disposed on the lower substrate. A second pad is disposed in a lower portion of the upper substrate. A solder structure is disposed between the first pad and the second pad. A coating layer covers a portion of a side surface of the solder structure. The solder structure includes a first portion disposed on a first surface that is in contact with the first pad. The first portion includes a first solder pattern including a first solder material and a second solder pattern. The second solder pattern surrounds the first solder pattern and includes a second solder material that is different from the first solder material. The coating layer includes a second solder material.

A semiconductor device includes a main board. A first bonding pad is disposed on the main board. A semiconductor package is disposed on the main board. A second bonding pad is disposed on a lower portion of the semiconductor package. A first solder structure is disposed between the first bonding pad and the second bonding pad. A first coating layer covers a portion of a side surface of the first solder structure. The semiconductor package includes a package substrate including an interconnection layer. A first connection pad is disposed on the package substrate. A semiconductor chip is electrically connected to the interconnection layer on the package substrate. A second connection pad is disposed in a lower portion of the semiconductor chip. A second solder structure is disposed between the first connection pad and the second connection pad. A second coating layer covers a portion of a side surface of the second solder structure. The first solder structure includes a first lower portion disposed on a first surface that is in contact with the first bonding pad. The first lower portion includes a first solder pattern and a second solder pattern. The second solder pattern surrounds the first solder pattern. The second solder structure includes a second lower portion disposed on a second surface that is in contact with the first connection pad. The second lower portion includes a third solder pattern and a fourth solder pattern surrounding the third solder pattern. The first and second coating layers and the second and fourth solder patterns include the same material.

### BRIEF DESCRIPTION OF DRAWINGS

The above and other aspects and features of the present disclosure will be more clearly understood from the following detailed description, taken in conjunction with the accompanying drawings, in which:

FIG. 1 is a cross-sectional view illustrating a semiconductor package according to example embodiments of the present disclosure;

FIG. 2 is an enlarged view illustrating an example embodiment of region A of the semiconductor package of FIG. 1;

FIGS. 3A to 3C are plan views illustrating example embodiments of a first surface of a solder structure that is in contact with the first connection pad of FIG. 2;

FIG. 4 is a plan view illustrating an example embodiment of a second surface of the solder structure that is in contact with the second connection pad of FIG. 2;

FIG. 5 is a plan view illustrating an example embodiment of an intermediate portion between a first surface and a second surface of the solder structure of FIG. 2;

FIG. 6 is a cross-sectional view illustrating a semiconductor package according to an example embodiment of the present disclosure;

FIG. 7 is an enlarged view illustrating an example embodiment of region B of the semiconductor package of FIG. 6;

FIG. 8 is a cross-sectional view illustrating a semiconductor module according to an example embodiment of the present disclosure;

FIG. 9A is a cross-sectional view illustrating an example embodiment of a method of manufacturing the semiconductor package of FIG. 1;

FIG. 9B is a cross-sectional view illustrating an example embodiment of a method of manufacturing the semiconductor package of FIG. 6; and

FIGS. 10A to 10E are cross-sectional views illustrating a method of manufacturing a semiconductor package according to example embodiments of the present disclosure.

### DETAILED DESCRIPTION

Hereinafter, example embodiments of the present disclosure will be described with reference to the accompanying drawings. The same reference numerals may be used to indicate the same components in the drawing and the specification, and to the extent that an element is not described in detail with respect to this figure, it may be understood that the element is at least similar to a corresponding element that has been described elsewhere within the present disclosure.

Embodiments of the present disclosure relate to a semiconductor package that features an innovative solder structure and coating layer designed to increase the mechanical and electrical reliability of the connections of the semiconductor device. This innovative structure consists of two distinct patterns: a high-melting-point solder material (e.g., Tin-Silver-Copper alloy) and a low-melting-point solder material (e.g., Tin-Bismuth alloy). These materials are alternately layered, with one surrounding the other, enhancing thermal and mechanical durability.

A coating layer is applied to part of the solder structure's external surface. This layer includes the same material as the lower melting-point solder, ensuring better adhesion and reducing defects like void formation.

By incorporating materials with varying melting points and a protective coating, the design aims to increase solder joint performance during thermal cycling and reduce failures such as tearing or delamination.

The semiconductor package, so arranged, is suitable for integration on substrates like PCBs or ceramic boards, making it well suited for high-performance computing or electronic systems requiring robust and reliable interconnects.

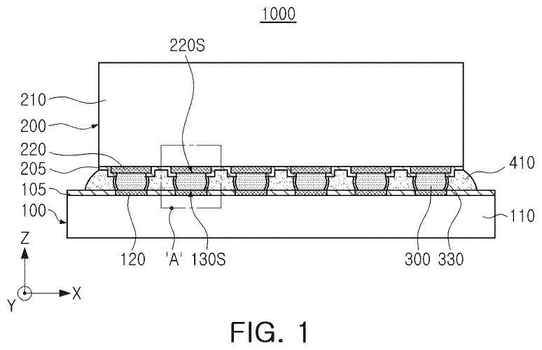

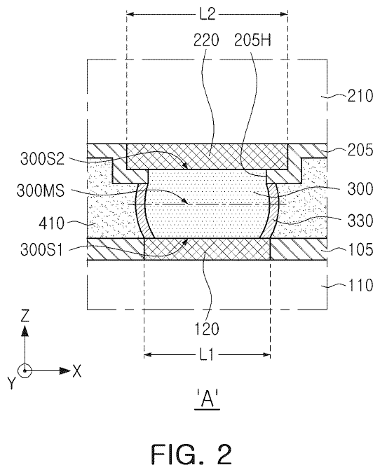

FIG. 1 is a cross-sectional view illustrating a semiconductor package according to example embodiments of the present disclosure. FIG. 2 is an enlarged view illustrating an example embodiment of region A of the semiconductor package of FIG. 1.

Referring to FIGS. 1 and 2, a semiconductor package 1000 may include a first structure 100, a second structure 200 disposed on the first structure 100, a first pad 120 disposed on an upper surface of the first structure 100, a second pad 220 disposed on a lower surface of the second structure 200, a solder structure 300 disposed between the first pad 120 and the second pad 220, a coating layer 330 covering at least a portion of an external surface of the solder structure 300, a first protection layer 105 disposed on the upper surface of the first structure 100, a second protection layer 205 disposed on the lower surface of the second structure 200, and an underfill material layer 410 filling a space between the first structure 100 and the second structure 200.

The first structure 100 may include a lower substrate 110. The first structure 100 may further include a circuit layer in the lower substrate 110. The circuit layer may include interconnection layers and vias connecting the interconnection layers. In an example, the first structure 100 may be a main board. In an example, a plurality of semiconductor package structures may be mounted on the upper surface of the first structure 100. In this case, the semiconductor package 1000 may be referred to as a semiconductor module.

The lower substrate 110 is a support substrate on which the second structure 200 is mounted, and may be a semiconductor package substrate including a printed circuit board (PCB), a ceramic substrate, a glass substrate, and a tape interconnection substrate. In an example, the lower substrate 110 may include different materials depending on the type of substrate. For example, if the lower substrate 101 is a printed circuit board, it may be constructed by adding an interconnection layer on one or both surfaces of an operating stack plate.

The lower substrate 110 may include an upper surface on which first pads 120 and a first protection layer 105 are disposed, and a lower surface opposing the upper surface.

The first pads 120 may be disposed on the lower substrate 110. The first pads 120 may be spaced apart from each other in a first direction (e.g., X-direction). The first pads 120 may be connected to integrated circuits or individual components in the lower substrate 110.

The first protection layer 105 may be disposed on an upper surface of the lower substrate 110, and may expose upper surfaces of each of the first pads 120. The first protection layer 105 may protect the lower substrate 110 from external physical and/or chemical damage.

The second structure 200 may be disposed on the first structure 100. The second structure 200 may be a single semiconductor package structure. In an example, the second structure 200 may include an upper substrate 210. The upper substrate 210 is a support substrate on which a plurality of semiconductor chips are mounted, and may be a semiconductor package substrate including a printed circuit board (PCB), a ceramic substrate, a glass substrate, and a tape interconnection substrate. In an example, the upper substrate 210 may include different materials depending on the type of the substrate. For example, when the upper substrate 210 is a printed circuit board, the upper substrate 210 may be in the form of additionally stacking an interconnection layer on one surface or both surfaces of a copper-clad stack plate. In an example, a solder resist layer may be disposed on the lower surface and upper surface of the upper substrate 210.

The upper substrate 210 may include a lower surface on which the second pads 220 and the second protection layer 205 are disposed, and an upper surface opposing the lower surface and having a plurality of semiconductor chips disposed thereon.

The second pads 220 may be disposed on the lower surface of the upper substrate 210. The second pads 220 may be spaced apart from each other in the first direction (e.g., X-direction) on the lower surface of the upper substrate 210. The second pads 220 may be connected to integrated circuits or individual components in the upper substrate 210.

The second protection layer 205 may be disposed on the lower surface of the upper substrate 210 and may have an opening 205H exposing at least a portion of each of the second pads 220. The second protection layer 205 may protect the upper substrate 210 from external physical and/or chemical damage. The second protection layer 205 may cover a portion of the side surface and the lower surface of the second pad 220.

The first pads 120 and the second pads 220 may include signal pads, power pads, and ground pads. The first and second pads 120 and 220 may include at least one of, for example, aluminum (Al), copper (Cu), nickel (Ni), tungsten (W), platinum (Pt), and gold (Au). In this document, the first pad 120 may be referred to as a first bonding pad, and the second pad 220 may be referred to as a second bonding pad.

The first protection layer 105 and the second protection layer 205 may be solder resist layers. The first protection layer 105 may include an insulating polymer, for example, Photosensitive Polyimide (PSPI), but the present disclosure is not necessarily limited thereto.

The first pad 120 may overlap the second pad 220 in the vertical direction (e.g., Z-direction). In an example, a first width L1 of the first pad 120 in the first direction (e.g., X-direction) may be smaller than a second width L2 of the second pad 220 in the first direction (e.g., X-direction). In an example, in a plan view, an area of the first pad 120 may be smaller than an area of the second pad 220.

A solder structure 300 may be disposed between the first pad 120 and the second pad 220. In an example, the solder structure 300 may be disposed between an upper surface of the first pad 120 and the lower surface of the second pad 220 exposed by the opening 205H of the second protection layer 205. In an example, the solder structure 300 might not overlap the first protection layer 105 and the second protection layer 205 in the vertical direction (e.g., Z-direction). For example, the coating layer 330 might not overlap the first protective layer 105 in the vertical direction (e.g., Z-direction).

The solder structure 300 may include a first surface 300S1 that is in contact with the first pad 120, a second surface 300S2 that is in contact with the second pad 220, and an intermediate portion 300 MS disposed between the first surface 300S1 and the second surface 300S2.

The solder structure 300 may include at least two or more alloys including tin (Sn). In an example, the solder structure 300 may include a first solder material and a second solder material that is different from the first solder material. In an example, the first solder material and the second solder material may be alloys including tin (Sn). In an example, the first solder material may include a first alloy including tin (Sn)-silver (Ag)-copper (Cu). The second solder material may be a second alloy including tin (Sn)-bismuth (Bi). In an example, the first alloy may have a first melting point, and the second alloy may have a second melting point that is lower than the first melting point. For example, the second alloy may include SAC305. In an example, the melting point of the first solder material may be greater than or equal to about 200° C. For example, the melting point of the first solder material may be between about 235° C. and about 245° C. The second solder material may be less than or equal to about 200° C., for example, between about 185° C. and about 195° C. As used herein, all stated ranges are understood to be inclusive and the term “about,” when used to describe temperatures, may be understood to mean within 10° C., within 5° C., or within 1° C.

The coating layer 330 may cover at least a portion of the external surface of the solder structure 300. In an example, the coating layer 330 may be in contact with the upper surface of the first pad 120, but might not be in contact with the lower surface of the second pad 220. The coating layer 330 may be in contact with a lower surface of the second protection layer 205 overlapping the second pad 220. In an example, the coating layer 330 may include the same material as the second solder material of the solder structure 300. For example, the coating layer 330 may include a second alloy including tin (Sn)-bismuth (Bi).

The external surface of the solder structure 300 may be covered with the second protection layer 205 and the coating layer 330.

The underfill material layer 410 may fill a space between the first structure 100 and the second structure 200. The underfill material layer 410 may fill a space between the solder structures 300 disposed between the first structure 100 and the second structure 200. The underfill material layer 410 may be formed in a capillary underfill (CUF) process, but the present disclosure is not necessarily limited thereto.

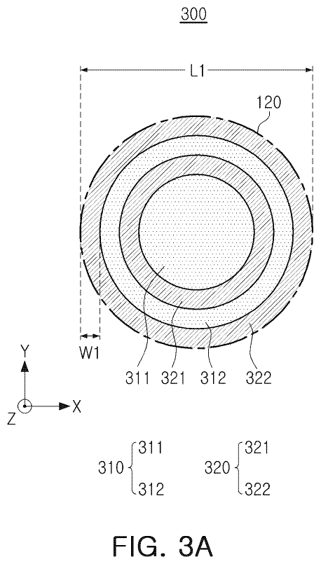

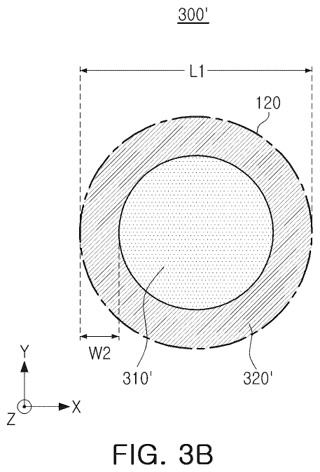

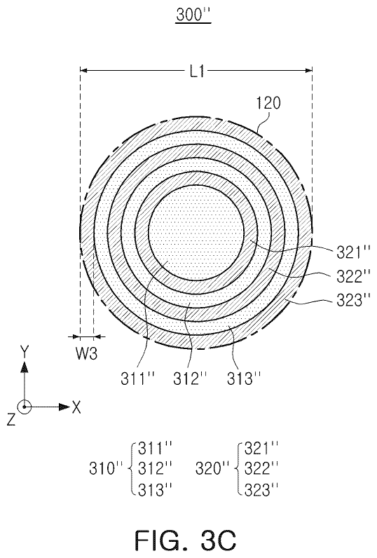

FIGS. 3A to 3C are plan views illustrating example embodiments of a first surface of a solder structure that is in contact with the first connection pad of FIG. 2. FIG. 3A is a plan view illustrating an example embodiment of a first surface 300S1 of a solder structure 300, FIG. 3B is a plan view illustrating an example embodiment of a first surface 300S1 of a solder structure 300′, and FIG. 3C is a plan view illustrating an example embodiment of a first surface 300S1 of a solder structure 300″.

Referring to FIG. 3A, the solder structure 300 includes a first surface 300S1 that is in contact with the first pad 120, and the solder structure 300 may include a first portion including a first solder pattern 310 and a second solder pattern 320 on the first surface 300S1. The first solder pattern 310 and the second solder pattern 320 may be alternately arranged. In an example, the second solder pattern 320 may be disposed in an outermost portion of the solder structure 300. The first surface 300S1 of the solder structure 300 may entirely overlap the first pad 120 in the vertical direction (e.g., Z-direction). In an example embodiment, the first solder pattern 310 and the second solder pattern 320 may be alternately arranged so as to entirely overlap the first pad 120. In an example embodiment, the first surface 300S1 of the solder structure 300 is the lower surface of the solder structure 300, and the area of the first surface 300S1 may be substantially equal to the area of the first pad 120.

The first solder pattern 310 may include the first solder material. The second solder pattern 320 may include a second solder material that is different from the first solder material. The first solder material may include a high-melting point solder material, and the second solder material may include a low-melting point solder material having a lower melting point than the first solder material. the second solder pattern 320 may include the same material as the coating layer 330 of FIG. 2. For example, the second solder pattern 320 and the coating layer 330 may include the second solder material.

In an example embodiment, the first solder material and the second solder material may be alloys including tin (Sn). In an example, the first solder material may include a first alloy including tin (Sn)-silver (Ag)-copper (Cu). The second solder material may be a second alloy including tin (Sn)-bismuth (Bi). In an example, the first alloy may have a first melting point, and the second alloy may have a second melting point lower than the first melting point.

The first solder pattern 310 may include a plurality of solder patterns including the first solder material. For example, first solder pattern 310 may include a 1-1 solder pattern 311 and a 1-2 solder pattern 312. The second solder pattern 320 may include a plurality of solder patterns including a second solder material. For example, the second solder pattern 320 may include a 2-1 solder pattern 321 and a 2-2 solder pattern 322. In an example, the 1-1 and 1-2 solder patterns 311 and 312 and the 2-1 and 2-2 solder patterns 321 and 322 may be alternately arranged. The 1-1 solder pattern 311 may be surrounded by the 2-1 solder pattern 321, the 2-1 solder pattern 321 may be surrounded by the 1-2 solder pattern 312, and the 1-2 solder pattern 312 may be surrounded by the 2-2 solder pattern 322. Each of the 1-2 solder pattern 312, the 2-1 solder pattern 321, and the 2-2 solder pattern 322 may have the same thickness. In an example, each of the 1-2 solder pattern 312, the 2-1 solder pattern 321, and the 2-2 solder pattern 322 may have a first thickness W1. For example, the first thickness W1 may be about 40 μm or more.

The 2-2 solder pattern 322 may be in contact with the coating layer 330 in the first portion of the solder structure 300. The coating layer 330 may be connected to the 2-2 solder pattern 322 of the first portion of the solder structure 300 that is in contact with the first pad 120.

Referring to FIG. 3B, the solder structure 300′ may include a first surface 300S1 that is in contact with the first pad 120, and the solder structure 300′ may include a first portion including a first solder pattern 310′ and a second solder pattern 320′ on the first surface 300S1. The first surface 300S1 of the solder structure 300′ may entirely overlap the first pad 120 in a vertical direction (e.g., Z-direction). Each of the first solder pattern 310′ and the second solder pattern 320′ may be one solder pattern. The first portion of the solder structure 300′ may include a first solder pattern 310′ and a second solder pattern 320′ surrounding the first solder pattern 310′. In an example, a second thickness W2 of the second solder pattern 320′ may be about 40 μm or more. The thickness of the first solder pattern 310′ may be thicker than the second thickness W2.

The second solder pattern 320′ may be in contact with the coating layer 330 in the first portion of the solder structure 300′. The coating layer 330 may be connected to the second solder pattern 320′ of the first portion of the solder structure 300′ that is in contact with the first pad 120.

Referring to FIG. 3C, the solder structure 300″ includes a first surface 300S1 that contacts the first pad 120, and the solder structure 300″ may include a first portion including a first solder pattern 310″ and a second solder pattern 320″ on the first surface 300S1. The first solder pattern 310″ and the second solder pattern 320″ may be alternately arranged. The second solder pattern 320″ may be disposed in an outermost portion of the solder structure 300″. The first surface 300S1 of the solder structure 300″ may entirely overlap the first pad 120 in the vertical direction (e.g., Z-direction).

The first solder pattern 310″ may include a 1-1 solder pattern 311″, a 1-2 solder pattern 312″, and a 1-3 solder pattern 313″. The second solder pattern 320″ may include a 2-1 solder pattern 321″, a 2-2 solder pattern 322″, and a 2-3 solder pattern 323″. In an example, the 1-1, 1-2, and 1-3 solder patterns 311″, 312″ and 313″ and the 2-1, 2-2, and 2-3 solder patterns 321″, 322″ and 323″ may be alternately arranged. In an example, the 1-1 solder pattern 311″ may be surrounded by the 2-1 solder pattern 321″, the 2-1 solder pattern 321″ may be surrounded by the 1-2 solder pattern 312″, the 1-2 solder pattern 312″ may be surrounded by the 2-2 solder pattern 322″, and the 2-2 solder pattern 322″ may be surrounded by the 1-3 solder pattern 313″. In an example, each of the 1-2 and 1-3 solder patterns 312″ and 313″ and the 2-1, 2-2, and 2-3 solder patterns 321″, 322″ and 323″ may have the same thickness. Each of the 1-2 and 1-3 solder patterns 312″ and 313″ and the 2-1, 2-2, and 2-3 solder patterns 321″, 322″ and 323″ may have a third thickness W3, for example, the third thickness W3 may be about 40 μm or more.

The 2-3 solder pattern 323″ of the first portion of the solder structure 300″ may be in contact with the coating layer 330. The coating layer 330 may be connected to the 2-3 solder pattern 323″ of the first portion of the solder structure 300″ that is in contact with the first pad 120.

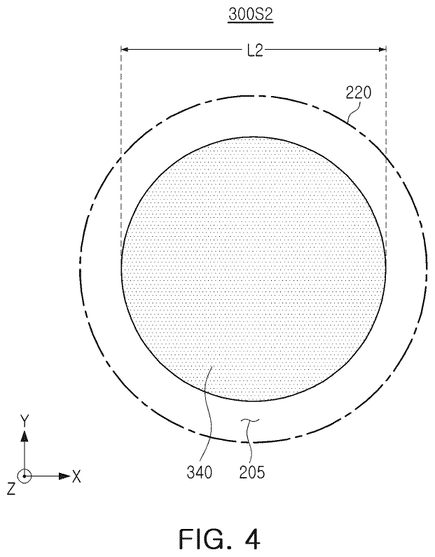

FIG. 4 is a plan view illustrating an example embodiment of a second surface a solder structure that is in contact with the second connection pad of FIG. 2.

Referring to FIG. 4, the solder structure 300 includes a second surface 300S2 that is in contact with the second pad 220, and the solder structure 300 may include a second portion including a fifth solder pattern 340 on the second surface 300S2. In an example, the second pad 220 may include a first region that is in contact with the second surface 300S2 of the solder structure 300 and a second region that is in contact with the second protection layer 205. The second portion of the solder structure 300 may be surrounded by the second protection layer 205. In an example, an area of the second surface 300S2 that is in contact with the second pad 220 may be smaller than an area of the second pad 220.

The fifth solder pattern 340 may include a first alloy including tin (Sn)-silver (Ag)-copper (Cu). In an example, the fifth solder pattern 340 may include the same material as the first solder material of the first solder pattern 310 of FIG. 3A.

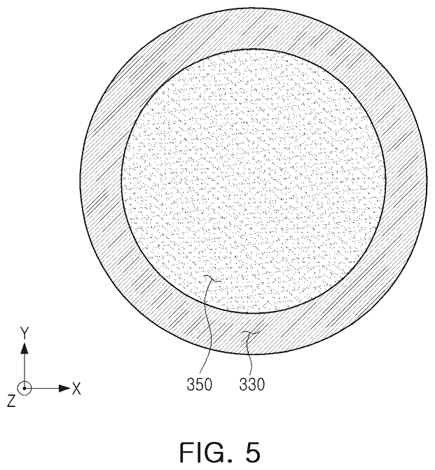

FIG. 5 is a plan view illustrating an example embodiment of an intermediate portion between the first surface and the second surface of the solder structure of FIG. 2.

Referring to FIG. 5, in the intermediate portion 300 MS between the first surface (e.g., the first surface 300S1 of FIG. 1) and the second surface (e.g., the second surface 300S2 of FIG. 1) of the solder structure 300, a sixth solder pattern 350 surrounded by a coating layer 330 may be included. The sixth solder pattern 350 may have a solder pattern different from the first portion and the second portion of the solder structure 300. The sixth solder pattern 350 may include a first solder material, a second solder material, tin (Sn), bismuth (Bi), and/or combinations thereof.

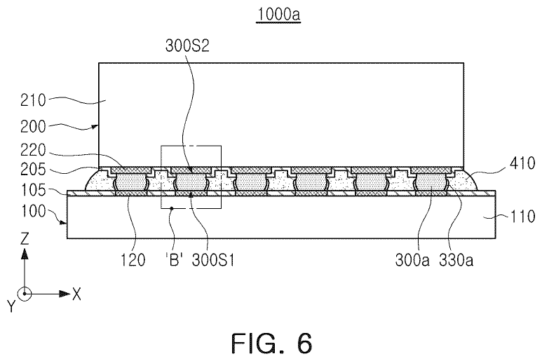

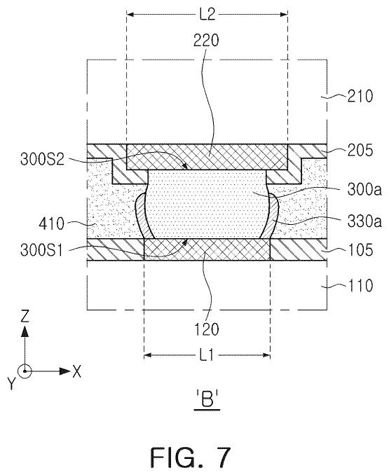

FIG. 6 is a cross-sectional view illustrating a semiconductor package according to an example embodiment of the present disclosure. FIG. 7 is an enlarged view illustrating an example embodiment of region B of the semiconductor package of FIG. 6.

Referring to FIG. 6 and FIG. 7, a semiconductor package 1000a may have various components that are identical to or otherwise corresponding to those illustrated in FIG. 1 except for a solder structure 300a and a coating layer 330a. To the extent that an element is not described in detail with respect to FIGS. 6 and 7, it may be understood that the element is at least similar to a corresponding element that has been described with respect to FIG. 1.

The coating layer 330a may cover a portion of an external surface of the solder structure 300a. In an example, the coating layer 330a may be in contact with an upper surface of the first pad 120, and might not be in contact with a lower surface of the second pad 220 and the second protection layer 205. The coating layer 330a may be disposed on a second side surface of the solder structure 300a adjacent to the second protection layer 205 from a first side surface of the solder structure 300a on the upper surface of the first pad 120. For example, a portion of the external surface of the solder structure 300a might not be covered by the coating layer 330a and the second protection layer 205. A portion of the external surface of the solder structure 300a may be left exposed. In an example, the solder structure 300a in the first surface 300S1 that is in contact with the first pad 120 may have a first portion, identical to the first surface 300S1 of the solder structures 300, 300′ and 300″ of FIGS. 3A, 3B, and 3C described above, and the solder structure 300a in the second surface 300S2 that is in contact with the second pad 220 may have a second portion, identical to the second surface 300S2 of the solder structure 300 of FIG. 4 described above.

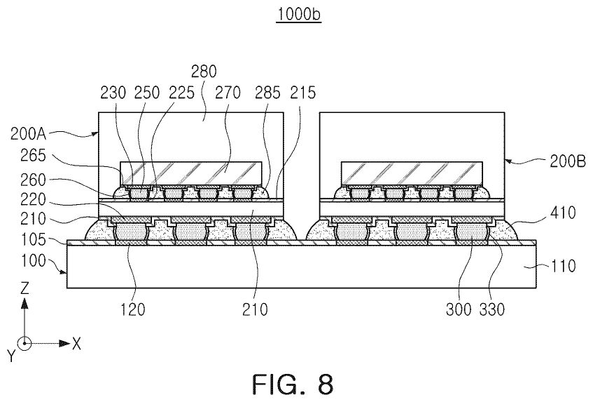

FIG. 8 is a cross-sectional view illustrating a semiconductor package according to an example embodiment of the present disclosure. Referring to FIG. 8, a semiconductor package 1000b may have configurations identical to or corresponding to those illustrated in FIG. 1 except for first and second semiconductor package structures 200A and 200B. To the extent that an element is not described in detail with respect to FIG. 8, it may be understood that the element is at least similar to a corresponding element that has been described with respect to FIG. 1.

Referring to FIG. 8, the semiconductor package 1000b may include a first structure 100, first and second semiconductor package structures 200A and 200B on the first structure 100, a first bonding pad 120 on the first structure 100, a second bonding pad 220 on lower surfaces of the first and second semiconductor package structures 200A and 200B, a first solder structure 300 disposed between the first bonding pad 120 and the second bonding pad 220, a first coating layer 330 covering at least a portion of the solder structure 300, a first protection layer 105 disposed on an upper surface of the first structure 100, a second protection layer 205 disposed on a lower surface of the second structure 200, and a first underfill material layer 410 filling a space between the first structure 100 and the first and second semiconductor package structures 200A and 200B.

Each of the first and second semiconductor package structures 200A and 200B may include: an upper substrate 210, a semiconductor chip 270 disposed on the upper substrate 210, first connection pads 225 disposed on an upper surface of the upper substrate 210, second connection pads 230 disposed on a lower surface of the semiconductor chip 270, a second solder structure 250 disposed between the first connection pad 225 and the second connection pad 230, a second coating layer 260 covering at least a portion of an external surface of the second solder structure 250, a third protection layer 215 disposed on the upper surface of the upper substrate 210, a fourth protection layer 265 disposed on the lower surface of the semiconductor chip 270, a second underfill material layer 285 filling a space between the upper substrate 210 and the semiconductor chip 270, and a sealant 280 surrounding a semiconductor chip 270 on the upper substrate 210.

The upper substrate 210 is a support substrate on which a semiconductor chip 270 is mounted, and may include a lower surface on which a second bonding pad 220 is disposed and an upper surface opposing the lower surface and having a first connection pad disposed thereon. The upper substrate 210 is a redistribution substrate and may include a plurality of redistribution layers and redistribution vias.

The semiconductor chip 270 may be disposed on the upper surface of the upper substrate 210, and a second connection pad 230 electrically connected to the redistribution layers (or integrated circuits) of the upper substrate 210 may be disposed on the lower surface of the semiconductor chip 270.

The semiconductor chip 270 may be an integrated circuit (IC) in a bare state in which a separate bump or a separate interconnection layer is not formed, but the present disclosure is not necessarily limited thereto, and the semiconductor chip 270 may be a packaged-type integrated circuit. The integrated circuit may be a processor chip such as a central processor (CPU), a graphic processor (GPU), a field programmable gate array (FPGA), an application processor (AP), a digital signal processor, an encryption processor, a microprocessor, a microcontroller, or the like, but the present disclosure is not necessarily limited thereto, and the integrated circuit may be a logic chip such as an analog-to-digital converter, an application-specific IC (ASIC), and the like, or a memory chip including a volatile memory such as a dynamic RAM (DRAM), a static RAM (SRAM), and the like, and a nonvolatile memory such as a phase change RAM (PRAM), a magnetic RAM (MRAM), a resistive RAM (RRAM), a flash memory, and the like.

The first connection pads 225 may have a component corresponding to the first bonding pad 120 on the upper surface of the lower substrate 110. In an example, the first connection pads 225 may be disposed on the upper surface of the upper substrate 210, and may be spaced apart from each other in the first direction (e.g., X-direction). The first connection pads 225 may be electrically connected to the redistribution layers (or integrated circuits) in the upper substrate 210.

The third protection layer 215 may have a component corresponding to the first protection layer 105 on the upper surface of the lower substrate 110. In an example, the third protection layer 215 may be disposed on the upper surface of the upper substrate 210, and may surround side surfaces of the first connection pads 225. For example, the third protection layer 215 may cover the upper surface of the upper substrate 210, and may leave an upper surface of the first connection pad 225 exposed.

The second connection pads 230 may have a component corresponding to the second bonding pads 220 on the lower surface of the upper substrate 210. In an example, the second connection pads 230 may be disposed on the lower surface of the semiconductor chip 270, and may be spaced apart in the first direction (e.g., X-direction). The second connection pads 230 may overlap the first connection pads 225 in the vertical direction (e.g., Z-direction).

The fourth protection layer 265 may have a component corresponding to the second protection layer 205 on the lower surface of the upper substrate 210. The fourth protection layer 265 may be disposed on the lower surface of the semiconductor chip 270 and may have an opening exposing at least a portion of each of the second connection pads 230.

The second solder structure 250 may have a component corresponding to the first solder structure 300 disposed between the first bonding pad 120 and the second bonding pad 220. The second solder structure 250 may include a third surface that is in contact with the first connection pad 225 and a fourth surface that is in contact with the second connection pad 230. In an example, the second solder structure 250 may include a first portion having a third solder pattern including a first solder material and a fourth solder pattern including a second solder material different from the first solder material. In an example, the third solder pattern of the second solder structure 250 may include the same first solder material as the first solder pattern of the first solder structure 300. The fourth solder pattern of the second solder structure 250 may include a second solder material identical to the second solder pattern of the first solder structure 300.

An area of the third surface of the second solder structure 250 that is in contact with the first connection pad 225 may be smaller than an area of the first surface of the first solder structure 300 that is in contact with the first bonding pad 120. In an example, an area of the fourth surface of the second solder structure 250 that is in contact with the second connection pad 230 may be smaller than an area of the second surface of the first solder structure 300 that is in contact with the second bonding pad 220.

The second coating layer 260 may correspond to the first coating layer 330 configured to cover at least a portion of an external surface of the first solder structure 300. The second coating layer 260 may cover at least a portion of the external surface of the second solder structure 250 of the second coating layer 260 and may be in contact with the upper surface of the first connection pad 225, but might not be in contact with a lower surface of the second connection pad 230. The second coating layer 260 may be in contact with a lower surface of the fourth protection layer 265 overlapping the second connection pad 230. However, the present disclosure is not necessarily limited thereto, and the second coating layer 260 might not be in contact with the fourth protection layer 265 in the vertical direction (e.g., Z-direction). In an example, the second coating layer 260 may include the same second solder material as the first coating layer 330.

The second underfill material layer 285 may correspond to the first underfill material layer 410 disposed between the first structure 100 and the first and second semiconductor package structures 200A and 200B. The second underfill material layer 285 may fill a space between the upper substrate 210 and the semiconductor chip 270 and a space between the second solder structures 250 disposed between the upper substrate 210 and the semiconductor chip 270.

The sealant 280 may cover at least a portion of the semiconductor chip 270 on the upper substrate 210. The sealant 280 may include, for example, a thermosetting resin such as an epoxy resin, a thermoplastic resin such as a polyimide, or a prepreg, ABF, FR-4, BT and Epoxy Molding Compound (EMC), in which an inorganic filler is impregnated in these resins. For example, the sealant 280 may include EMC.

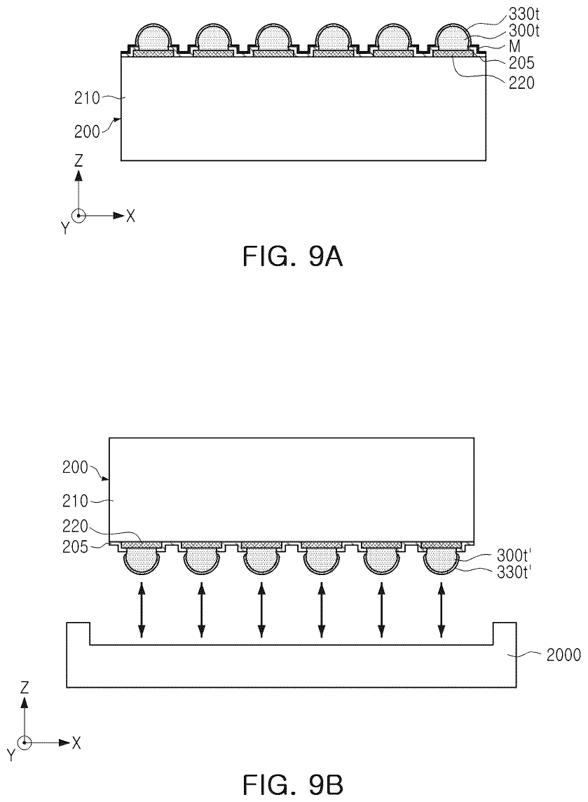

FIG. 9A is a cross-sectional view illustrating an example embodiment of a method for manufacturing a semiconductor package of FIG. 1.

Referring to FIG. 9A, the method for manufacturing a semiconductor package may include: an operation of forming second pads 220 spaced apart from each other in the first direction (e.g., X-direction) on one surface of a second structure 200; an operation of forming a second protection layer 205 exposing at least a portion of an upper surface of the second pads 220; an operation of forming a first solder ball 300t including a first solder material on the upper surface of the exposed second pads 220; and an operation of forming a first coating film 330t including a second solder material different from the first solder material on an external surface of the first solder ball 300t using a mask layer M covering an upper surface of a second protection layer 205. The method for manufacturing a semiconductor package may further include an operation of performing a first reflow process after forming the first coating film 330t.

The first solder material may include a first alloy including tin (Sn)-silver (Ag)-copper (Cu), and the second solder material may include a second alloy including tin (Sn)-bismuth (Bi). In an example, a melting point of the first solder material may be higher than a melting point of the second solder material.

A process for forming the first coating film 330t may utilize a vapor deposition process, a coating process, and the like, using a mask layer M. In an example, the first reflow process is a process for soldering the first solder ball 300t and the first coating film 330t, and a reflow temperature of the first reflow process may be about 230° C. to 240° C.

FIG. 9B is a cross-sectional view illustrating an example embodiment of a method for manufacturing a semiconductor package of FIG. 6.

Referring to FIG. 9B, the method for manufacturing a semiconductor package may include: an operation of forming second pads 220 spaced apart from each other in the first direction (e.g., X-direction) on one surface of a second structure 200; an operation of forming a second protection layer 205 exposing at least portions of upper surfaces of the second pads 220; an operation of forming a first solder ball 300t including a first solder material on the upper surfaces of the exposed second pads 220; and an operation of forming a first coating film 330t′ including a second solder material different from the first solder material on a portion of the external surface of the first solder ball 300t through a dipping coating process using a coating device 2000 so that the first solder ball 300t is disposed in a lower portion of the second structure 200. The method for manufacturing a semiconductor package may further include an operation of performing a second reflow process after forming the first coating film 330t′.

The first coating film 330t′ may be applied to the external surface of the first solder ball 300t′ adjacent to the second protection layer 205. The first coating film 330t′ may be applied only to a portion of the external surface of the first solder ball 300t′ so as not to come into contact with the second protection layer 205. A portion of the first solder ball 300t′ that is not applied by the first coating film 330t′ may be left exposed.

The second reflow process is a process for soldering the first solder ball 300t′ and the first coating film 330t′, and a reflow temperature of the second reflow process may be about 230° C. to 240° C. In an example embodiment, a melting point of the first solder material may be higher than a melting point of the second solder material.

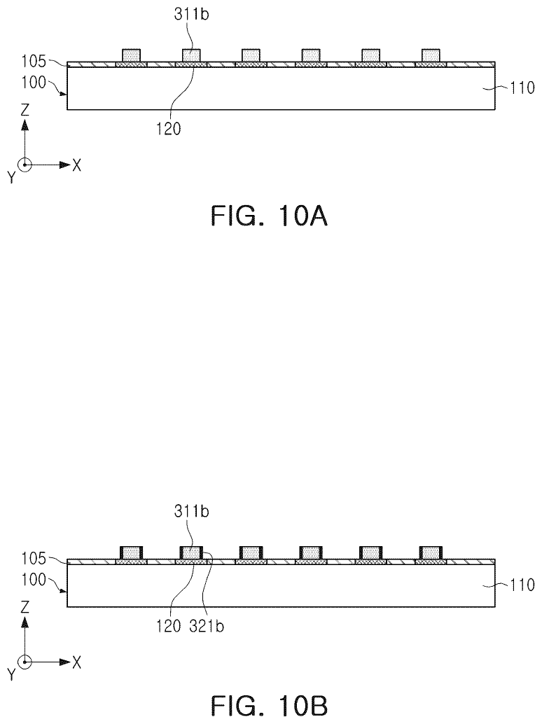

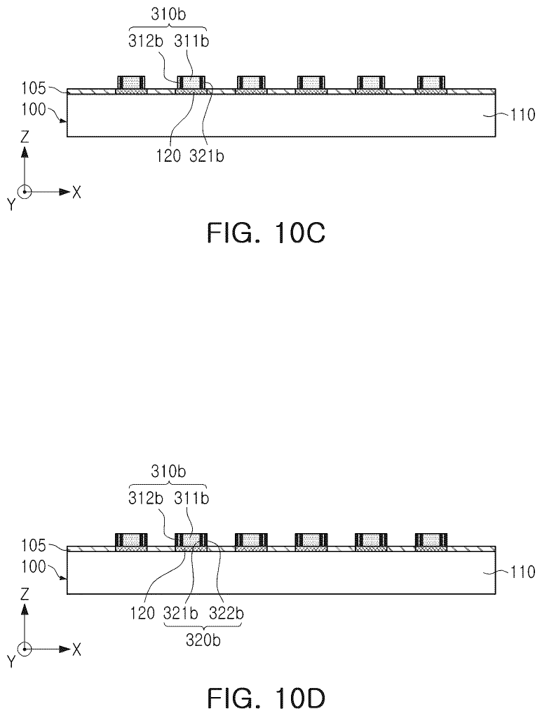

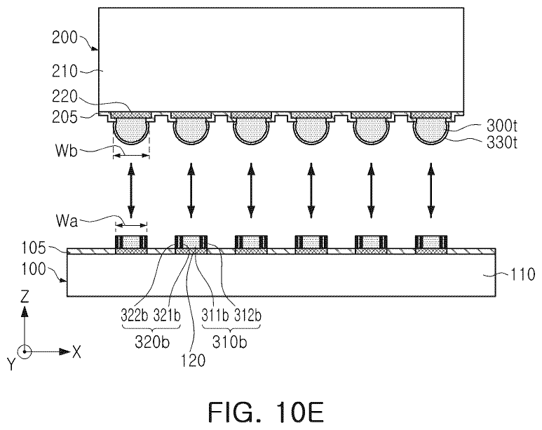

FIGS. 10A to 10E are cross-sectional views illustrating a method for manufacturing a semiconductor package according to example embodiments of the present disclosure.

Referring to FIGS. 10A to 10E, a method for manufacturing a semiconductor package may include an operation of forming solder paste patterns 310b and 320b on the first pads 120 of the first structure 100 (see FIGS. 10A to 10D) and an operation of combining a first solder ball 300t in which an external surface thereof is at least partially covered with the solder paste patterns 310b and 320b on an upper surface of the first structure 100 and a coating film 330t on a lower surface of the second structure 200 (see FIG. 10E).

Referring to FIGS. 10A to 10D, the operation of forming the solder paste patterns 310b and 320b may include an operation of sequentially forming a 1-1 solder pattern 311b including a first solder material on each of the first pads 120, an operation of forming a 2-1 solder pattern 321b including a second solder material different from the first solder material and surrounding the 1-1 solder pattern 311b, an operation of forming a 1-2 solder pattern 312b including the first solder material, and an operation of forming a 2-2 solder pattern 322b including the second solder material.

Each of the solder paste patterns 310b and 320b may entirely overlap each of the first pads 120.

The first solder pattern 310b is illustrated as including two solder patterns, by including the 1-1 solder pattern 311b and the 1-2 solder pattern 312b, but the present disclosure is not necessarily limited thereto, and the first solder pattern 310b may include solder patterns including one or three or more first solder materials. The second solder pattern 320b is also illustrated as including two solder patterns, by including the 2-1 solder pattern 321b and the 2-2 solder pattern 322b, but the present disclosure is not necessarily limited thereto, and the second solder pattern 320b may include solder patterns including one or three or more second solder materials intersecting the first solder pattern 310b.

Referring to FIG. 10E, a method for manufacturing a semiconductor package may include an operation of disposing a second structure 200 formed on a lower surface of a first solder ball 300t in which an external surface is at least partially covered with a coating film 330t, on the first structure 100 having solder paste patterns 310b and 320b formed therein, and an third reflow process operation of soldering the first solder balls 300t in which external surfaces thereof are at least partially covered with the solder paste patterns 310b and 320b and the coating film 330t. A reflow temperature of the third reflow process may be about 185° C. to 195° C.

Each of the first solder balls 300t in which the external surfaces thereof are at least partially covered with the solder paste patterns 310b and 320b and the coating film 330t may overlap each other in the vertical direction (e.g., Z-direction). In an example, a width Wa of the solder paste patterns 310b and 320b in the first direction (e.g., X-direction) may be smaller than a maximum width Wb of the first solder ball 300t in which the external surface thereof is covered with the coating film 330t.

The first solder ball 300t covered with the solder paste patterns 310b and 320b and the coating film 330t may be combined in the third reflow process. A 2-2 solder pattern 322b disposed in an outermost portion of the solder paste patterns 310b and 320b may be combined with the coating film 330t to form the coating layer 330 of FIG. 1. The 2-2 solder pattern 322b and the coating film 330t may be more easily combined as they include the same second solder material. The first solder pattern 310b of the solder paste patterns 310b and 320b and the 2-1 solder pattern 321b may be in contact with the first solder ball 300t covered with the coating film 330t to form the solder structure 300 of FIG. 1.

The method for manufacturing a semiconductor package, according to example embodiments of the present disclosure, may include a process of combining the first solder ball 300t covered with the solder paste patterns 310b and 320b formed on the upper surface of the first structure 100 and the coating film 330t formed on the lower surface of the second structure 200 through the reflow process, thereby improving problems (e.g., tearing phenomenon, void generation, and the like) due to combining different heterogeneous materials and providing a semiconductor package including a solder structure having increased mechanical and electrical reliability.

While example embodiments have been illustrated and described above, it will be apparent to those skilled in the art that modifications and variations could be made within the scope of the present disclosure.

What is claimed is:

1. A semiconductor device, comprising:
a lower substrate;
a first pad disposed on the lower substrate;
an upper substrate disposed on the lower substrate;
a second pad disposed in a lower portion of the upper substrate;
a solder structure disposed between the first pad and the second pad; and
a coating layer covering at least a portion of an external surface of the solder structure,
wherein the solder structure includes a first portion disposed on a first surface that is in contact with the first pad, and
wherein the first portion includes a first solder pattern and a second solder pattern, the second solder pattern surrounding the first solder pattern.

2. The semiconductor device of claim 1, wherein the first solder pattern has a melting point that is higher than a melting point of the second solder pattern.

3. The semiconductor device of claim 2, wherein the coating layer includes a same material as the second solder pattern.

4. The semiconductor device of claim 1, wherein the coating layer is in contact with the second solder pattern.

5. The semiconductor device of claim 1, wherein the first portion of the solder structure entirely overlaps the first pad in a vertical direction.

6. The semiconductor device of claim 1, wherein an area of the first pad is smaller than an area of the second pad.

7. The semiconductor device of claim 1, wherein the solder structure includes a second portion disposed on a second surface that is in contact with the second pad and facing the first surface, and the second portion includes a same material as the first solder pattern.

8. The semiconductor device of claim 7, further comprising:
a first protection layer surrounding a side surface of the first pad; and
a second protection layer covering the second pad and including an opening exposing at least a portion of an upper surface of the second pad.

9. The semiconductor device of claim 8, wherein the coating layer does not contact the first protection layer in a vertical direction.

10. The semiconductor device of claim 8, wherein the second protection layer is in contact with a side surface of the second portion of the solder structure.

11. The semiconductor device of claim 1, wherein the first portion of the solder structure includes a third solder pattern surrounded by the first solder pattern and including a same material as the second solder pattern, and a fourth solder pattern surrounded by the third solder pattern and including a same material as the first solder pattern.

12. The semiconductor device of claim 1, wherein a portion of the external surface of the solder structure is left exposed by the coating layer.

13. The semiconductor device of claim 1, wherein the first solder pattern includes an alloy of tin (Sn), silver (Ag) and copper (Cu), and
wherein the second solder pattern includes an alloy of tin (Sn) and bismuth (Bi).

14. A semiconductor device, comprising:
a lower substrate;
a first pad disposed on the lower substrate;
an upper substrate disposed on the lower substrate;
a second pad disposed in a lower portion of the upper substrate;
a solder structure disposed between the first pad and the second pad; and
a coating layer covering a portion of a side surface of the solder structure, wherein the solder structure includes a first portion disposed on a first surface that is in contact with the first pad,
wherein the first portion includes a first solder pattern including a first solder material and a second solder pattern,
wherein the second solder pattern surrounds the first solder pattern and includes a second solder material that is different from the first solder material, and
wherein the coating layer includes the second solder material.

15. The semiconductor device of claim 14, wherein the first solder material has a melting point that is within a range of 235° C. to 245° C., inclusive, and
wherein the second solder material has a melting point that is within a range of 185° C. to 195° C., inclusive.

16. The semiconductor device of claim 14, wherein the solder structure includes the first surface and a second surface opposing the first surface, the second surface is in contact with the second pad, and the solder structure includes an intermediate portion disposed between the first surface and the second surface,
wherein the intermediate portion is surrounded by the first solder pattern and the first solder pattern and the intermediate portion includes a third solder pattern that is different from the first and second solder patterns.

17. The semiconductor device of claim 14, wherein an area of the second pad is larger than an area of an upper surface of the solder structure that is in contact with the second pad.

18. The semiconductor device of claim 14, wherein an area of the first pad is equal to an area of a lower surface of the solder structure that is in contact with the first pad.

19. A semiconductor device, comprising:
a main board;
a first bonding pad disposed on the main board;
a semiconductor package disposed on the main board;
a second bonding pad disposed on a lower portion of the semiconductor package;
a first solder structure disposed between the first bonding pad and the second bonding pad; and
a first coating layer covering a portion of a side surface of the first solder structure,
wherein the semiconductor package includes:
a package substrate including an interconnection layer;
a first connection pad disposed on the package substrate;
a semiconductor chip electrically connected to the interconnection layer on the package substrate;
a second connection pad disposed in a lower portion of the semiconductor chip;
a second solder structure disposed between the first connection pad and the second connection pad; and
a second coating layer configured to cover a portion of a side surface of the second solder structure,
wherein the first solder structure includes a first lower portion disposed on a first surface that is in contact with the first bonding pad,
wherein the first lower portion includes a first solder pattern and a second solder pattern, the second solder pattern surrounding the first solder pattern,
wherein the second solder structure includes a second lower portion disposed on a second surface that is in contact with the first connection pad,
wherein the second lower portion has a third solder pattern and a fourth solder pattern surrounding the third solder pattern, and
wherein the first and second coating layers and the second and fourth solder patterns include a same material.

20. The semiconductor device of claim 19, wherein in a plan view, an area of the first surface is larger than an area of the second surface.
